(19) United States
(12) Patent Application Publication
(10) Pub. No.: US 2012/0241090 A1
(43) Pub. Date: Sep. 27, 2012

(54) PLASMA PROCESSING APPARATUS

(75) Inventors: Jun Yoshikawa, Sendai (JP); Naoki Matsumoto, Sendai (JP); Naoki Mihara, Sendai (JP); Wataru Yoshikawa, Sendai (JP); Shota Yoshimura, Sendai (JP); Kazuki Takahashi, Sendai (JP)

(73) Assignee: TOKYO ELECTRON LIMITED, Tokyo (JP)

(21) Appl. No.: 13/429,638

(22) Filed: Mar. 26, 2012

(30) Foreign Application Priority Data
Mar. 25, 2011 (JP) 2011-067835
Jul. 7, 2011 (JP) 2011-150982
Mar. 21, 2012 (JP) 2012-063856

(51) Int. Cl. B05C 9/00; H01L 21/3065

(52) U.S. Cl. 156/345.41

(57) ABSTRACT

A plasma processing apparatus includes a processing chamber; a gas supply unit for supplying a processing gas into the processing chamber; a microwave generator for generating microwave; an antenna for introducing the microwave for plasma excitation into the processing chamber; a coaxial waveguide provided between the microwave generator and the antenna; a holding unit, disposed to face the antenna in a direction of a central axis line of the coaxial waveguide, for holding a processing target substrate; a dielectric window, provided between the antenna and the holding unit, for transmitting the microwave from the antenna into the processing chamber; and a dielectric rod provided in a region between the holding unit and the dielectric window along the central axis line.

### CROSS-REFERENCE TO RELATED APPLICATION

This application claims the benefit of Japanese Patent Application Nos. 2011-067835, 2011-150982, and 2012-63856 filed on Mar. 25, 2011, Jul. 7, 2011, and Mar. 21, 2012, respectively, the entire disclosures of which are incorporated herein by reference.

### FIELD OF THE INVENTION

The present disclosure relate to a plasma processing apparatus.

### BACKGROUND OF THE INVENTION

A plasma processing apparatus is described in Patent Document 1. The plasma processing apparatus described in Patent Document 1 includes a processing chamber, a microwave generator, a coaxial waveguide, an antenna, a dielectric window, a gas introduction unit, a holding unit and a plasma shield member.

The antenna receives microwave generated by the microwave generator via the coaxial waveguide, and the microwave is introduced into the processing chamber through the dielectric window. Further, a processing gas is introduced into the processing chamber by the gas introduction unit. The gas introduction unit includes a ring-shaped center gas nozzle.

Especially, in the plasma processing apparatus of Patent Document 1, plasma of the processing gas is generated within the processing chamber by the microwave supplied through the antenna, and a processing target substrate mounted on the holding unit is processed by the plasma. Further, in the plasma processing apparatus of Patent Document 1, in order to uniform a processing rate of the processing target substrate, the plasma shield member is provided at a middle portion between a central portion and an edge portion.

Patent Document 1: Japanese Patent Laid-open Publication No. 2008-124424

The gas introduction unit of Patent Document 1 has the ring-shaped center gas nozzle. In Patent Document 1, it is described that the size of the ring-shaped center gas nozzle needs to be minimized. Further, Patent Document 1 also describes providing the plasma shield member at the middle portion in order to prevent a processing rate at the edge portion of the processing target substrate from becoming higher than a processing rate at the central portion of the processing target substrate.

Meanwhile, the present inventor has conducted researches repeatedly and found out that the processing rate at the central portion of the processing target substrate may become higher than the processing rate at the edge portion of the processing target substrate.

Accordingly, in the plasma processing apparatus, it is required to reduce the processing rate at the central portion of the processing target substrate.

### BRIEF SUMMARY OF THE INVENTION

In accordance with one aspect of an illustrative embodiment, there is provided a plasma processing apparatus including a processing chamber, a gas supply unit, a microwave generator, an antenna, a coaxial waveguide, a holding unit, a dielectric window and a dielectric rod. The gas supply unit is configured to supply a processing gas into the processing chamber. The microwave generator is configured to generate microwave. The antenna is configured to introduce the microwave for plasma excitation into the processing chamber. The coaxial waveguide is provided between the microwave generator and the antenna. The holding unit for holding thereon a processing target substrate is disposed to face the antenna in a direction of a central axis line of the coaxial waveguide. The dielectric window for transmitting the microwave from the antenna into the processing chamber is provided between the antenna and the holding unit. The dielectric rod is provided in a region between the holding unit and the dielectric window along the central axis line.

In this plasma processing apparatus, the dielectric rod is positioned in a central region within the processing chamber. Here, the central region refers to a region that is positioned between the dielectric window and the holding unit along a central axis line X. The dielectric rod shields plasma in the central region. Accordingly, in this plasma processing apparatus, at the central region of the processing target substrate, a processing rate for the processing target substrate can be decreased.

A distance between a leading end of the dielectric rod which faces the holding unit and the holding unit may be smaller than or equal to about 95 mm. When the distance between the leading end of the dielectric rod and the holding unit is smaller than or equal to about 95 mm, plasma density in a region directly above the holding unit near the central axis line X can be effectively decreased.

A radius of the dielectric rod may be greater than or equal to about 60 mm. By setting the dielectric rod to have the radius greater than or equal to about 60 mm, plasma density in the region directly above the holding unit near the central axis line X can be effectively decreased.

The gas supply unit may be configured to supply the processing gas from the antenna side to the holding unit side along the central axis line. Further, the dielectric rod may be provided with one or more holes through which the processing gas supplied from the gas supply unit passes, and the holes may extend along the central axis line. With this configuration, the processing gas is introduced into the processing chamber through the holes of the dielectric rod along the central axis line. Further, a metal film may be formed on inner surfaces of the holes. Due to the film, it is possible to prevent plasma from being generated within the holes.

In accordance with another aspect of an illustrative embodiment, there is provided a plasma processing apparatus including a circular plate instead of the dielectric rod provided in the plasma processing apparatus in accordance with one aspect. The circular plate is provided in a region between a holding unit and a dielectric window along a plane perpendicular to the central axis line. In this plasma processing apparatus, at the central region of the processing target substrate, a processing rate for the processing target substrate can be decreased.

A distance between the circular plate and the holding unit may be smaller than or equal to about 95 mm. When the distance between the circular plate and the holding unit is smaller than or equal to about 95 mm, plasma density in the region directly above the holding unit near the central axis line X can be effectively decreased.

A radius of the circular plate may be greater than or equal to about 60 mm. By setting the circular plate to have the radius greater than or equal to about 60 mm, plasma density in the region directly above the holding unit near the central axis line X can be more effectively decreased.

The circular plate may be supported by a dielectric rod. The dielectric rod may be provided along the central axis line and have a diameter smaller than a diameter of the circular plate. The dielectric rod may be provided with one or more holes through which the processing gas supplied from the gas supply unit passes, and the holes may extend along the central axis line. Further, a metal film may be formed on inner surfaces of the holes.

The gas supply unit may be configured to supply the processing gas from the antenna side to the holding unit side along the central axis line, and the circular plate may be provided with a hole extending along the central axis line. That is, the circular plate may be an annular plate. With this configuration, a processing gas can flow along the central axis line from the hole of the circular plate, and regardless of presence of the hole, plasma density in the central region can be decreased by the circular plate.

The plasma processing apparatus may further include a gas pipe, formed in an annular shape centered about the central axis line, having a multiple number of gas discharge holes. The circular plate may be supported by the gas pipe. Further, the plasma processing apparatus may further include a multiple number of supporting rods extending in a radial direction with respect to the central axis line and coupled to the gas pipe and the circular plate.

A distance between the holding unit and the gas pipe in a direction of the central axis line may be smaller than a distance between the circular plate and the holding unit. Accordingly, the gas is discharged from the gas discharge holes of the gas pipe in the direction of the central axis line, and an updraft gas flow of the gas can be changed to a downdraft gas flow. Due to the flow of the processing gas, a processing rate in a region (i.e., middle region) between a central portion and an edge portion of the processing target substrate, or a processing rate at the edge of the processing target substrate can be equivalent to a processing rate at the central portion of the processing target substrate W. The circular plate may have a mesh shape. By appropriately adjusting the size of the mesh holes, the amount of discharged gas, which is split into an updraft gas flow and a downdraft gas flow, from the gas discharge holes 42b of the gas pipe 42a can be controlled.

Further, a thickness of each of the supporting rods may be smaller than or equal to about 5 mm. By setting the supporting rod to have the radius greater than or equal to about 60 mm, the influence of the supporting rods on the plasma distribution can be relatively reduced.

The gas pipe may be provided directly below the circular plate in a direction of the central axis line. Further, the gas discharge holes of the gas pipe may be oriented to discharge gas downward or obliquely downward. The gas pipe may be provided along an outer periphery of the circular plate and may be in contact with a bottom surface of the circular plate. With this configuration, a direction of a gas discharged from the annular gas pipe can be adjusted so as to reduce non-uniformity of the processing rate the processing target substrate.

The gas pipe may have a cross section of a substantially rectangular shape. Further, the cross section of the gas pipe may have a first width in a direction perpendicular to the central axis line and a second width in a direction parallel to the central axis line, and, the first width may be larger than the second width or the second width may be larger than the first width. Due to such a configuration of the gas pipe, a pressure loss in the gas pipe can be decreased while reducing manufacturing cost of the gas pipe.

As described above, in accordance with the illustrative embodiments, it is possible to provide a plasma processing apparatus capable of reducing a processing rate at the central portion of the processing target substrate.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a cross sectional view schematically showing a plasma processing apparatus in accordance with a first illustrative embodiment;

FIG. 2 is an enlarged cross sectional view of a dielectric window and a dielectric rod shown in FIG. 1;

FIG. 3 is a graph showing an electron density distribution in a radial direction obtained through a simulation;

FIG. 4 is a graph showing an electron density distribution in the radial direction obtained through a simulation;

FIG. 5 provides graphs showing plasma distributions in the radial direction obtained through simulations;

FIG. 6 is a cross sectional view schematically showing a plasma processing apparatus in accordance with a second illustrative embodiment.

FIG. 7 is an enlarged cross sectional view showing a dielectric window and a circular plate made of a dielectric material illustrated in FIG. 6;

FIG. 8 is a graph showing a plasma distribution in the radial direction obtained through a simulation;

FIG. 9 is a graph showing a plasma distribution in the radial direction obtained through a simulation;

FIG. 10 is graph showing a plasma distribution in the radial direction obtained through a simulation;

FIG. 11 is a cross sectional view schematically showing a plasma processing apparatus in accordance with a third illustrative embodiment;

FIG. 12 is a broken perspective view showing some parts of the plasma processing apparatus shown in FIG. 11;

FIG. 13 is a graph showing a plasma distribution in the radial direction obtained through a simulation;

FIG. 14 is a graph showing a plasma distribution in the radial direction obtained through simulation;

FIG. 15 is graph showing a plasma distribution in the radial direction obtained through a simulation;

FIG. 16 is a diagram for describing a method for calculating evaluation values of uniformity of electron density in a circumferential direction;

FIG. 17 schematically shows a sample for an evaluation experiment;

FIG. 18 shows a circular plate in accordance with a fourth illustrative embodiment;

FIG. 19 provides a graph showing a plasma distribution in the radial direction obtained through simulations;

FIG. 20 is a broken perspective view showing some parts of a plasma processing apparatus in accordance with the fourth illustrative embodiment;

FIG. 21 provides cross sectional views schematically illustrating structures of a gas pipe provided in the plasma processing apparatus shown in FIG. 20; and

FIG. 22 shows cross sectional views schematically illustrating structures of a gas pipe provided in the plasma processing apparatus shown in FIG. 20.

### DETAILED DESCRIPTION OF THE INVENTION

Hereinafter, illustrative embodiments will be described in detail with reference to the accompanying drawings. In the drawings, same parts having substantially the same function and configuration will be assigned same reference numerals.

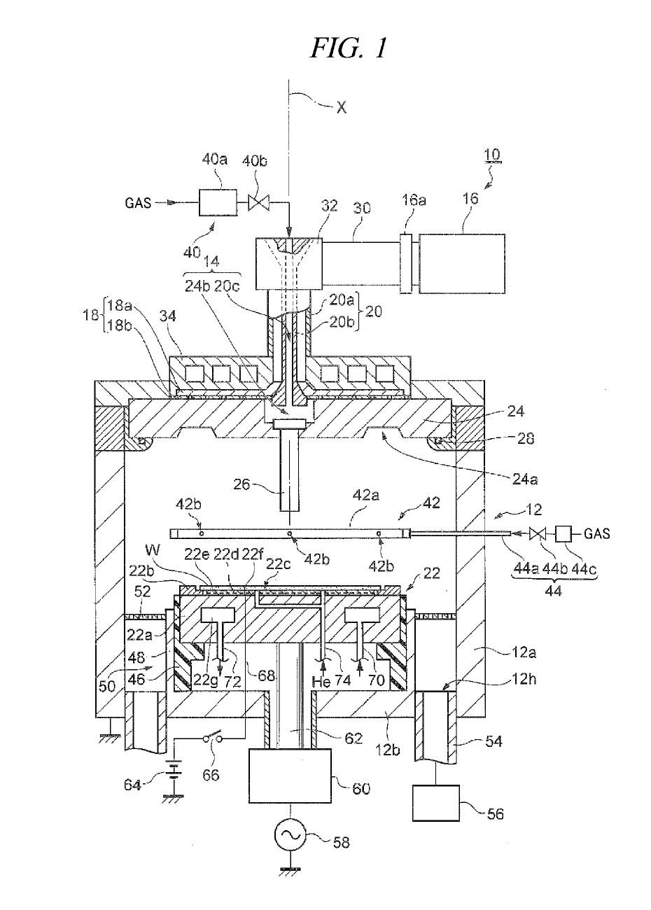

FIG. 1 is a cross sectional view schematically illustrating a plasma processing apparatus in accordance with an illustrative embodiment. The plasma processing apparatus 10 shown in FIG. 1 includes a processing chamber 12, a gas supply unit 14, a microwave generator 16, an antenna 18, a coaxial waveguide 20, a holding unit 22, a dielectric window 24 and a dielectric rod 26.

Within the processing chamber 12, a processing space in which a plasma process is performed on a processing target substrate W is formed. The processing chamber 12 has a sidewall 12a and a bottom 12b. The sidewall 12a has a substantially cylindrical shape extending in a direction of a central axis line X. The bottom 12b is provided at a lower end of the sidewall 12a. A gas exhaust hole 12h for gas exhaust is formed in the bottom 12b. An upper end of the sidewall 12a is open, and an opening at the upper end of the sidewall 12a is covered by the dielectric window 24. An O-ring 28 is provided between the dielectric window 24 and the upper end of the sidewall 12a. By the O-ring 28, the processing chamber 12 can be more securely sealed airtightly.

The microwave generator 16 generates microwave having a frequency of, e.g., about 2.45 GHz. The microwave generator 16 has a tuner 16a. The microwave generator 16 is connected to an upper portion of the coaxial waveguide 20 via a waveguide 30 and a mode converter 32. The coaxial waveguide 20 extends along the central axis line X. The coaxial waveguide 20 includes an outer conductor 20a and an inner conductor 20b. The outer conductor 20a has a cylindrical shape extending in the direction of the central axis line X. A lower end of the outer conductor 20a is electrically connected with an upper portion of a cooling jacket 34. The inner conductor 20b is provided inside the outer conductor 20a. The inner conductor 20b extends along the central axis line X, and a lower end of the inner conductor 20b is connected to a slot plate 18b of the antenna 18.

The antenna 18 includes a dielectric plate 18a and the slot plate 18b. The dielectric plate 18a has a substantially circular plate shape. The dielectric plate 18a is made of, e.g., quartz, alumina, or the like. The dielectric plate 18a is held between the slot plate 18b and a bottom surface of the cooling jacket 34. That is, the antenna 18 includes the dielectric plate 18a, the slot plate 18b and the bottom surface of the cooling jacket 34.

The slot plate 18b is a substantially circular metal plate provided with a multiple number of slot pairs. In the illustrative embodiment, the antenna 18 may be a radial line slot antenna. That is, the multiple number of slot pairs, each having two slot holes extending in intersecting or orthogonal directions to each other, are arranged at the slot plate 18b at regular intervals in a radial direction and in a circumferential direction of the slot plate 18b. The microwave generated by the microwave generator 16 is transmitted to the dielectric plate 18a through the coaxial waveguide 20 and is introduced into the dielectric window 24 from the slot holes of the slot plate 18b.

The dielectric window 24 has a substantially circular plate shape and is made of, e.g., quartz, alumina, or the like. The dielectric window 24 is positioned directly under the slot plate 18b. The dielectric window 24 transmits and introduces the microwave received from the antenna 18 into the processing space. Accordingly, an electric field is generated directly under the dielectric window 24, and plasma is generated within the processing space. As described above, in the plasma processing apparatus 10, the plasma can be generated by the microwave without applying a magnetic field.

In the illustrative embodiment, a recess 24a is formed at the bottom surface of the dielectric window 24. The recess 24a is formed in a ring shape about the central axis line X as its center and has a tapered shape. In the recess 24a, generation of a standing wave can be accelerated by the microwave, and the plasma can be effectively generated by the microwave.

In the plasma processing apparatus 10, a processing gas is supplied into the processing space through the gas supply unit 14 in the direction of the central axis line X from the antenna side to the holding unit side. In the illustrative embodiment, the gas supply unit 14 includes an inner hole 20c of the inner conductor 20b and a hole 24b of the dielectric window 24. That is, the inner conductor 20b as a cylindrical conductor serves as a part of the gas supply unit 14. Further, the dielectric window 24 having the hole 24b serves as the other part of the gas supply unit 14.

As shown in FIG. 1, the processing gas from a gas supply system 40 is supplied into the hole 24b of the dielectric window 24 through the inner hole 20c of the inner conductor 20b. The gas supply system 40 includes a flow rate controller 40a such as a mass flow controller and an opening/closing valve 40b. The processing gas supplied into the hole 24b is introduced into the processing space via the dielectric rod 26, as will be described later.

In the illustrative embodiment, the plasma processing apparatus 10 further includes another gas supply unit 42. The gas supply unit 42 includes a gas pipe 42a. The gas pipe 42a extends in a circular shape about the central axis line X between the dielectric window 24 and the holding unit 22. The gas pipe 42a is provided with a multiple number of gas discharge holes 42b through which a gas is discharged toward the central axis line X. The gas supply unit 42 is connected with a gas supply system 44.

The gas supply system 44 includes a gas pipe 44a, an opening/closing valve 44b and a flow rate controller 44c such as a mass flow controller. A processing gas is supplied into the gas pipe 42a of the gas supply unit 42 via the flow rate controller 44c, the opening/closing valve 44b and the gas pipe 44a. Further, the gas pipe 44a is inserted into the sidewall 12a of the processing chamber 12. The gas pipe 42a of the gas supply unit 42 is supported at the sidewall 12a via the gas pipe 44a.

The holding unit 22 is provided within the processing space so as to face the antenna 18 in the direction of the central axis line X. The holding unit 22 holds thereon the processing target substrate W. In the illustrative embodiment, the holding unit 22 includes a holding table 22a, a focus ring 22b and an electrostatic chuck 22c.

The holding table 22a is supported on a cylindrical support 46. The cylindrical support 46 is made of an insulating material and extends vertically upward from the bottom 12b. Further, a conductive cylindrical support 48 is provided at an outer surface of the cylindrical support 46. The cylindrical support 48 extends vertically upward from the bottom 12b of the processing chamber 12 along the outer surface of the cylindrical support 46. A ring-shaped gas exhaust path 50 is formed between the cylindrical support 46 and the sidewall 12a.

A baffle plate 52 having a multiple number of through holes is provided above the gas exhaust path 50. A gas exhaust device 56 is connected to a lower portion of the gas exhaust hole 12h via a gas exhaust pipe 54. The gas exhaust device 56 has a vacuum pump such as a turbo molecular pump. By the gas exhaust device 56, the processing space within the processing chamber 12 can be depressurized to a desired vacuum level.

The holding table 22a also serves as a high frequency electrode. A high frequency power supply 58 for RF bias is electrically connected to the holding table 22a via a matching unit 60 and a power supply rod 62. The high frequency power supply 58 outputs a high frequency power of a frequency, e.g., about 13.65 MHz suitable for controlling energy of ions attracted toward the processing target substrate W. The matching unit 60 includes a matching device for matching impedance at the side of the high frequency power supply 58 with impedance at a load side such as an electrode, plasma and the processing chamber 12. The matching device includes a blocking capacitor for generating a self bias.

The electrostatic chuck 22c is provided on a top surface of the holding table 22a. The electrostatic chuck 22c electrostatically holds thereon the processing target substrate W by an electrostatic attracting force. The focus ring 22b is provided outside the electrostatic chuck 22c in a radial direction so as to surround the processing target substrate W in a ring shape. The electrostatic chuck 22c includes an electrode 22d, an insulating film 22e and an insulating film 22f. The electrode 22d is formed of a conductive film and is positioned between the insulating film 22e and the insulating film 22f. The electrode 22d is electrically connected with a high-voltage DC power supply 64 via a switch 66 and a coated line 68. The electrostatic chuck 22c can attract and hold the processing target substrate W by a Coulomb force generated by a DC voltage applied from the DC power supply 64.

A ring-shaped coolant path 22g extending in a circumferential direction of the holding table 22a is formed within the holding table 22a. A coolant of a certain temperature, e.g., cooling water, from a chiller unit (not shown) is supplied into and circulated through the coolant path 22g via pipes 70 and 72. By adjusting the temperature of the coolant, the temperature of the processing target substrate W on the electrostatic chuck 22c can be controlled. Further, a heat transfer gas such as a He gas from a heat transfer gas supply unit (not shown) is supplied into a gap between the top surface of the electrostatic chuck 22c and a rear surface of the processing target substrate W.

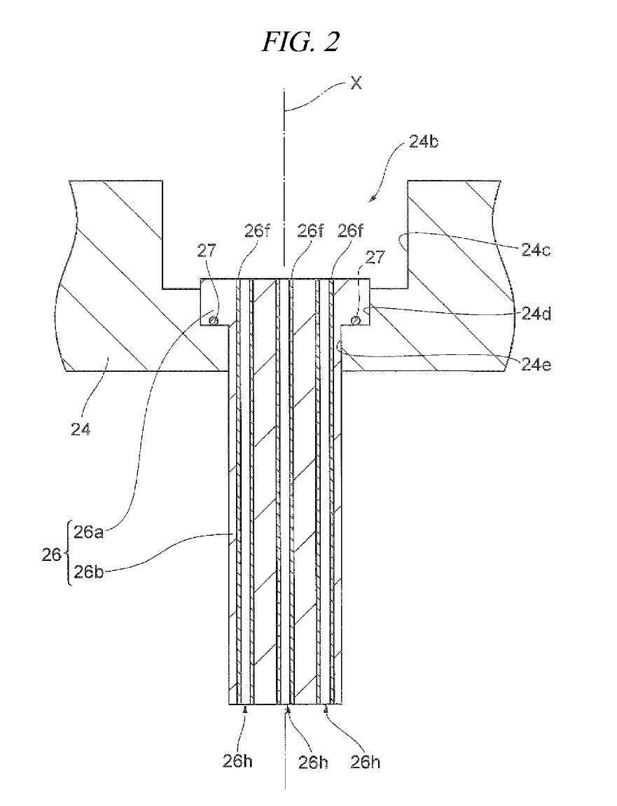

There will be explained with reference to FIGS. 1 and 2. FIG. 2 is an enlarged cross sectional view of a dielectric window and a dielectric rod shown in FIG. 1. A dielectric rod 26 is a substantially cylindrical dielectric member provided along the central axis line X. The dielectric rod 26 is made of, e.g., quartz or alumina.

In the present illustrative embodiment, the dielectric rod 26 is supported by the dielectric window 24. More specifically, the dielectric window 24 has, as surfaces for partitioning the hole 24b, a surface 24c, a surface 24d and a surface 24e in a sequence from the top. A diameter of the hole partitioned by the surface 24c is greater than a diameter of a hole partitioned by the surface 24d. The diameter of the hole partitioned by the surface 24d is greater than a diameter of a hole partitioned by the surface 24e.

The dielectric rod 26 includes a first portion 26a and a second portion 26b in a sequence from the top. The first portion 26a has substantially the same diameter as that of the hole partitioned by the surface 24d. Further, the second portion 26b has substantially the same diameter as that of the hole partitioned by the surface 24e. The second portion 26b extends to the processing space after passing through the hole partitioned by the surface 24e. The dielectric rod 26 is supported by the dielectric window such that a bottom surface of the first portion 26a is brought into contact with a step-shaped surface between the surface 24d and the surface 24e. Due to the first portion 26a and the second portion 26b, the hole 24b within the dielectric window 24 is isolated from the processing space within the processing chamber 12. In the present illustrative embodiment, an O-ring 27 is provided between the bottom surface of the first portion 26a and the step-shaped surface between the surface 24d and the surface 24e.

The second portion 26b of the dielectric rod 26 shields plasma in a central region of the processing space. The central region refers to a region that is positioned between the dielectric window 24 and the holding unit 22 along the central axis line X. The dielectric rod 26 positioned in the central region shields the plasma in the central region. Accordingly, at a portion on the processing target substrate W through which the central axis line X passes, a processing rate for the processing target substrate W is decreased.

In the illustrative embodiment, the second portion 26b of the dielectric rod 26 has a circular cross-section and a radius of the second portion 26b of the dielectric rod 26 is greater than or equal to about 60 mm. By setting the dielectric rod 26 to have the radius greater than or equal to about 60 mm, plasma density in a region directly above the holding unit 22 near the central axis line X can be effectively decreased. Further, a distance (gap) between a leading end (lower end) of the dielectric rod 26 and a top surface of the holding unit 22 is smaller than or equal to about 95 mm. Due to the gap, the plasma density in the region directly above the holding unit 22 near the central axis line X can be further effectively decreased.

In the present illustrative embodiment, as shown in FIG. 2, one or more holes 26h extending along the central axis line X are formed in the dielectric rod 26. The holes 26h communicate the hole 24b within the dielectric window 24 with the processing space within the processing chamber 12. Accordingly, the processing gas supplied from the gas supply unit 14 is introduced into the processing space through the dielectric rod 26. In the present illustrative embodiment, films 26f are formed on inner surfaces of the holes 26h. The films 26f may include, e.g., a metal film containing Au. Due to the films 26f, it is possible to prevent plasma from being generated within the holes 26h. Further, the films 26f are electrically grounded. In addition, a film may be formed on an outer surface of the dielectric rod 26, and the film may be an Y₂O₃ film having plasma resistance property.

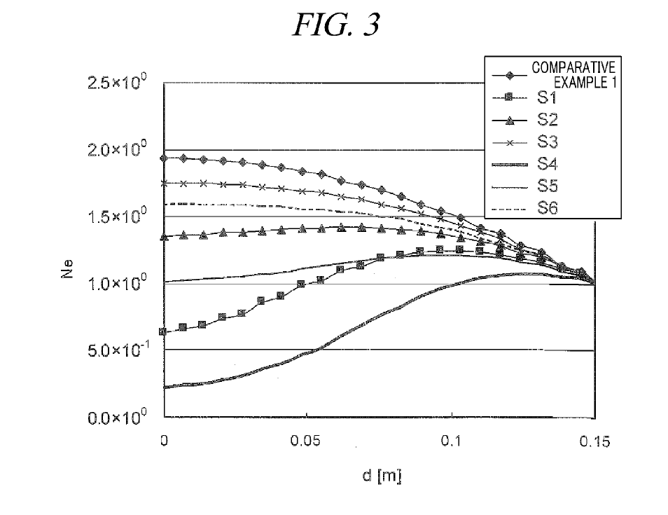

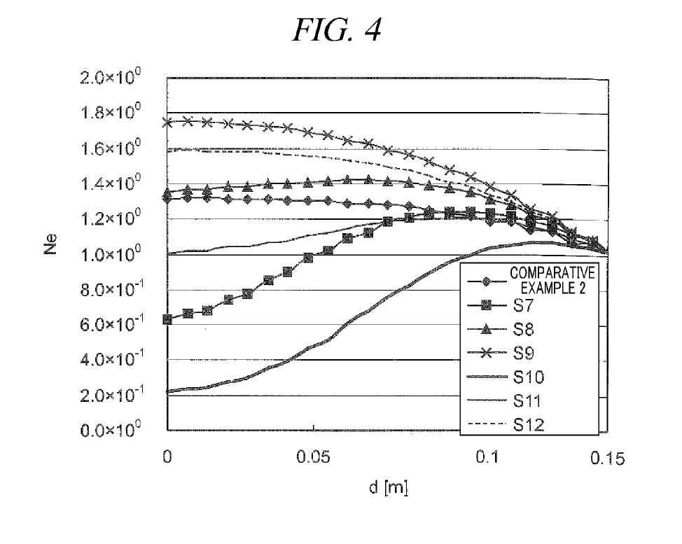

Hereinafter, simulation results of the plasma processing apparatus 10 shown in FIG. 1 will be described. FIGS. 3 and 4 are graphs showing electron density distributions in a radial direction obtained through the simulations. The simulation results S1 to S12 of FIGS. 3 and 4 show the electron density distributions in the radial direction measured while variously changing the parameters of the plasma processing apparatus 10 through the simulations. The electron density distributions in the radial direction are measured at a region upwardly spaced apart from the holding unit 22 by about 5 mm. In FIGS. 3 and 4, horizontal axes indicate a distance d from the central axis line X in the radial direction, and vertical axes indicate electron density (Ne) normalized by electron density measured in a region with a radius of about 15 cm from the central axis line X.

The simulation results shown in FIG. 3 are obtained when an argon (Ar) gas is used as a processing gas and an internal pressure of the processing chamber 12 is set to be about 20 mTorr (about 2.666 Pa). The results shown in FIG. 4 are obtained when an Ar gas is used as a processing gas and an internal pressure of the processing chamber 12 is set to be about 100 mTorr (about 13.33 Pa). Both of the results shown in FIGS. 3 and 4 are obtained by setting a gap between the top surface of the holding unit 22 and the bottom surface of the dielectric window 24 to be about 245 mm. The other parameters in the simulations of FIGS. 3 and 4 are given as follows.

Comparative examples 1 and 2: no dielectric rod

S1 and S7: a diameter of a dielectric rod 26 being about 60 mm, and a length of the dielectric rod 26 within the processing space being about 200 mm
S2 and S8: a diameter of a dielectric rod 26 being about 60 mm, and a length of the dielectric rod 26 within the processing space being about 150 mm
S3 and S9: a diameter of a dielectric rod 26 being about 60 mm, and a length of the dielectric rod 26 within the processing space being about 100 mm
S4 and S10: a diameter of a dielectric rod 26 being about 120 mm, and a length of the dielectric rod 26 within the processing space being about 200 mm
S5 and S11: a diameter of a dielectric rod 26 being about 120 mm, and a length of the dielectric rod 26 within the processing space being about 150 mm
S6 and S12: a diameter of a dielectric rod 26 being about 120 mm, and a length of the dielectric rod 26 within the processing space being about 100 mm

Here, the length of the dielectric rod 26 within the processing space refers to a length of the dielectric rod 26 extending below the dielectric window 24

Referring to FIG. 3, it can be seen that when an internal pressure of the processing space within the processing chamber 12 is relatively low, the electron density near the central axis line X can be reduced as compared to that in the comparative example 1 regardless of the types of the dielectric rods 26 of the simulation results (S1˜S6). It can be also seen that the electron density near the central axis line X can be effectively reduced by setting the dielectric rod 26 to have the diameter of about 120 mm or more (i.e., the radius of about mm or more). In addition, it can be seen that the electron density near the central axis line X can be more effectively reduced by setting the length of the dielectric rod 26 within the processing space to be about 150 mm or more, i.e., by setting the gap between the leading end (the lower end) of the dielectric rod 26 and the top surface of the holding unit 22 to be about 95 mm or less.

Referring to FIG. 4, it can be seen that when an internal pressure of the processing space within the processing chamber 12 is relatively high, the electron density near the central axis line X can be reduced as compared to that in the comparative example 2 by using the dielectric rods 26 of the simulation results (S7, S8, S10 and S11). That is, when the internal pressure of the processing space within the processing chamber 12 is relatively high, the electron density near the central axis line X can be reduced by setting the length of the dielectric rod 26 within the processing space to be about 150 mm or more, i.e., by setting the gap between the leading end (lower end) of the dielectric rod 26 and the top surface of the holding unit 22 to be about 95 mm or less.

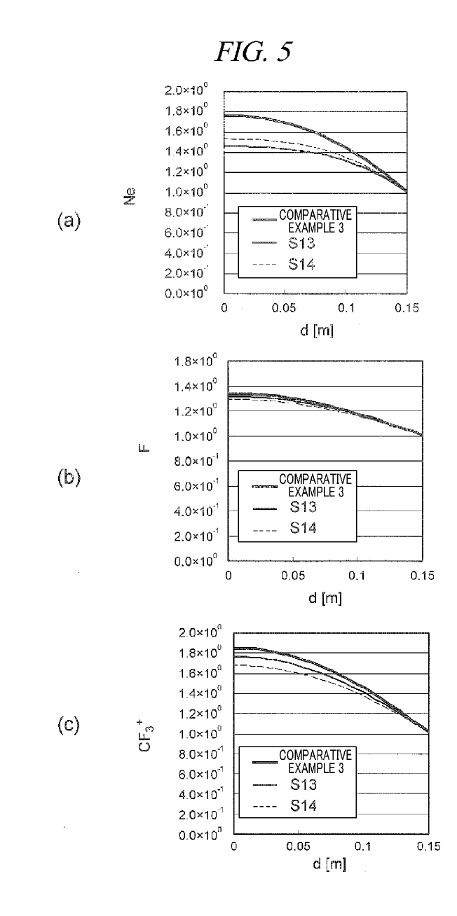

Hereinafter, there will be explained with reference with FIG. 5. FIGS. 5(a) to 5(c) are graphs showing plasma distributions in a radial direction obtained through simulations. The simulation results S13 and S14 of FIGS. 5(a) to 5(c) show an electron density (Ne) distribution in the radial direction (FIG. 5(a)), a fluorine (F) density distribution in the radial direction (FIG. 5(b)), and a CF₃⁺ density distribution in the radial direction (FIG. 5(c)), respectively. Here, the distributions are measured at a region upwardly spaced apart from the holding unit 22 by about 5 mm while variously changing the parameters of the plasma processing apparatus 10 through the simulations.

In FIG. 5, a horizontal axis indicates a distance d from the central axis line X in the radial direction. A vertical axis in FIG. 5(a) indicates electron density (Ne) normalized by electron density measured in a region with a radius of about 15 cm from the central axis line X. The vertical axis in FIG. 5(b) indicates fluorine density normalized by fluorine density measured in a region with a radius of about 15 cm from the central axis line X. The vertical axis in FIG. 5(c) indicates CF₃⁺ density normalized by CF₃⁺ density measured in a region with a radius of about 15 cm from the central axis line X.

The results shown in FIG. 5 are obtained when an Ar gas and a CHF₃ gas are used as processing gases and an internal pressure of the processing chamber 12 is set to be about 20 mTorr. Moreover, a flow rate ratio between the Ar gas and the CHF₃ gas is set to be about 500:25, and a gap between the top surface of the holding unit 22 and the bottom surface of the dielectric window 24 is set to be about 245 mm. The other parameters of the simulations of FIGS. 5(a) to 5(c) are given as follows.

Comparative example 3: no dielectric rod

S13: a diameter of a dielectric rod 26 being about 60 mm, and a length of the dielectric rod 26 within the processing space being about 100 mm
S14: a diameter of a dielectric rod 26 being about 120 mm, and a length of the dielectric rod 26 within the processing space being about 100 mm

Referring to FIG. 5, it can be seen that the electron density near the central axis line X can be reduced as compared to that in the comparative example 3 regardless of the types of the dielectric rods 26 of the simulation results (S13 and S14).

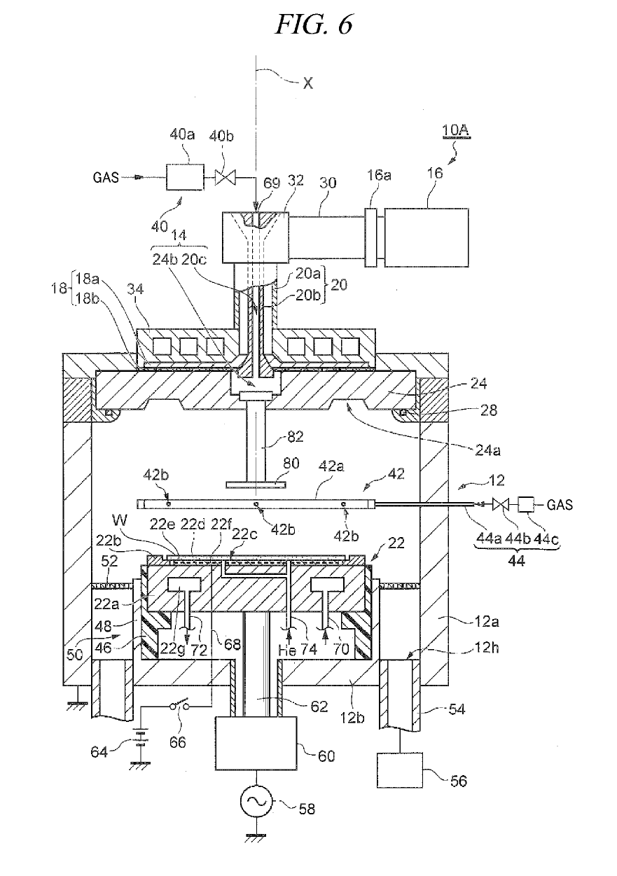

Hereinafter, a plasma processing apparatus in accordance with a second illustrative embodiment will be described. FIG. 6 is a cross sectional view schematically showing a plasma processing apparatus in accordance with the second illustrative embodiment. Hereinafter, the differences between the plasma processing apparatus 10 and a plasma processing apparatus 10A shown in FIG. 6 will be described.

The plasma processing apparatus 10A includes a circular plate 80 instead of the dielectric rod 26. The circular plate 80 is made of a dielectric material such as quartz or alumina, and has an approximately circular plate shape. The circular plate 80 is provided on a surface perpendicular to the central axis line X within the processing space between the dielectric window 24 and the holding unit 22. That is, in the plasma processing apparatus 10A, the circular plate 80 made of a dielectric material is positioned at the central region. The circular plate 80 shields plasma in the central region. Therefore, at a portion on the processing target substrate W through which the central axis line X passes, a processing rate for the processing target substrate W is decreased.

A radius of the circular plate 80 is greater than or equal to about 60 mm. By setting the dielectric circular plate 80 to have the radius greater than or equal to about 60 mm, plasma density in a region directly above the holding unit 22 near the central axis line X can be effectively decreased. Further, a distance (gap) between the bottom surface of the circular plate 80 and the top surface of the holding unit 22 is smaller than or equal to about 95 mm. Due to the gap, the plasma density in the region directly above the holding unit 22 near the central axis line X can be further effectively decreased.

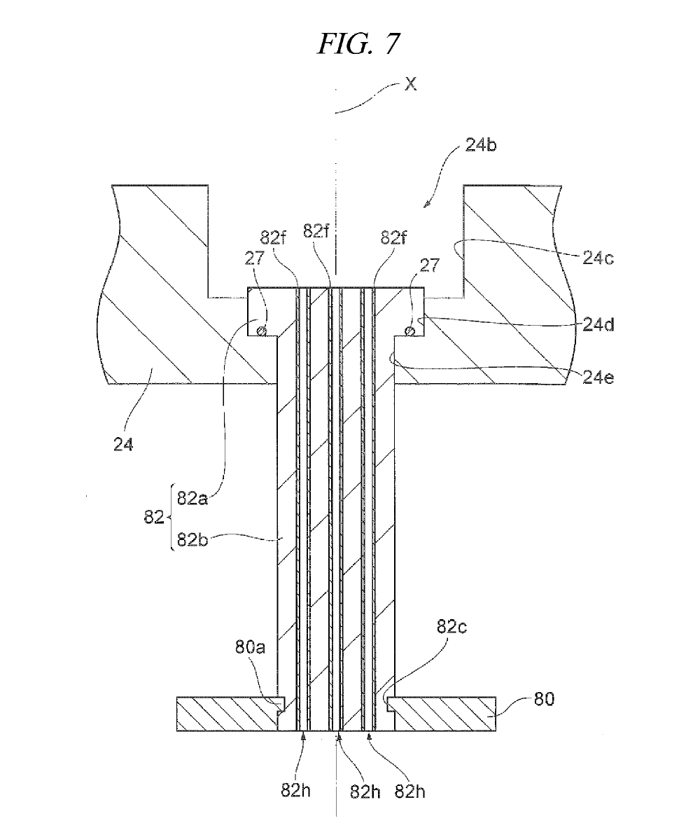

FIG. 7 is an enlarged cross sectional view showing the dielectric window and the dielectric circular plate illustrated in FIG. 6. In the present illustrative embodiment, as shown in FIG. 7, the circular plate 80 is supported by the dielectric window 24 via a dielectric rod 82. Further, the dielectric rod 82 is made of, e.g., quartz, alumina or the like.

The dielectric rod 82 includes a first portion 82a and a second portion 82b in a sequence from the top. The first portion 82a has substantially the same diameter as that of the hole partitioned by the surface 24d. Further, the second portion 82b has substantially the same diameter as that of the hole partitioned by the surface 24e. The dielectric rod 82 is supported by the dielectric window 24 such that a bottom surface of the first portion 82a is brought into contact with a step-shaped surface between the surface 24d and the surface 24e. Due to the first portion 82a and the second portion 82b, the hole 24b within the dielectric window 24 is isolated from the processing space within in the processing chamber 12. In the present illustrative embodiment, an O-ring 27 is positioned between the bottom surface of the first portion 82a and the step-shaped surface between the surface 24d and the surface 24e.

The second portion 82b has a small-diameter portion 82c formed at a lower end portion thereof. A diameter of the small-diameter portion 82c is smaller than that between both ends of the second portion 82b in the central axis line X. Meanwhile, a hole is formed in the center of the circular plate 80 along the central axis line X. Within the hole, an upper region has a diameter smaller than that of a lower region, and the upper region and the lower region within the hole are partitioned by a protrusion 80a of the circular plate 80. The protrusion 80a is connected with the small-diameter portion 82c of the dielectric rod 82. Accordingly, the circular plate 80 can be supported by the dielectric window 24 via the dielectric rod 82.

In the present illustrative embodiment, a multiple number of holes 82h extending along the central axis line X are formed in the dielectric rod 82. The holes 82h allow the hole 24b within the dielectric window 24 to communicate with the processing space. Accordingly, the processing gas supplied from the gas supply unit 14 is supplied into the processing space within the processing chamber 12 through the dielectric rod 82. In the present illustrative embodiment, films 82f are formed on inner surfaces of the holes 82h. The films 82f may include, e.g., a metal film containing Au. Due to the films 82f, it is possible to prevent plasma from being generated within the holes 82h. Further, the films 82f are electrically grounded. In addition, a film may be formed on an outer surface of the dielectric rod 82. The film may be a Y₂O₃ film having plasma resistance property.

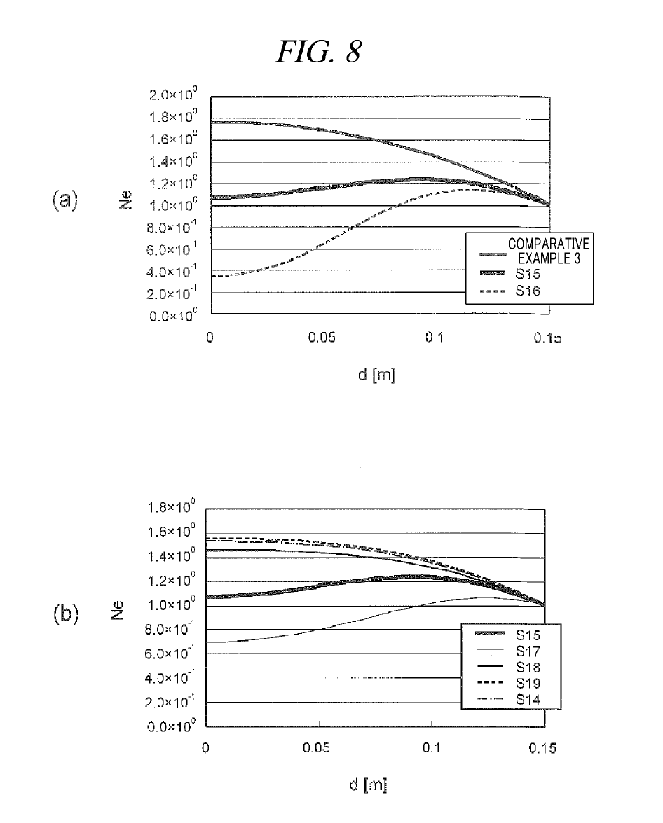

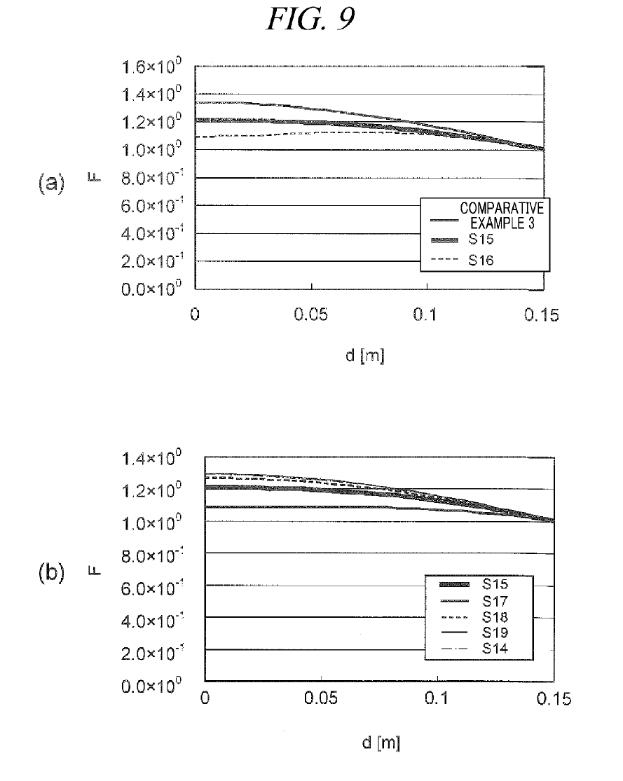

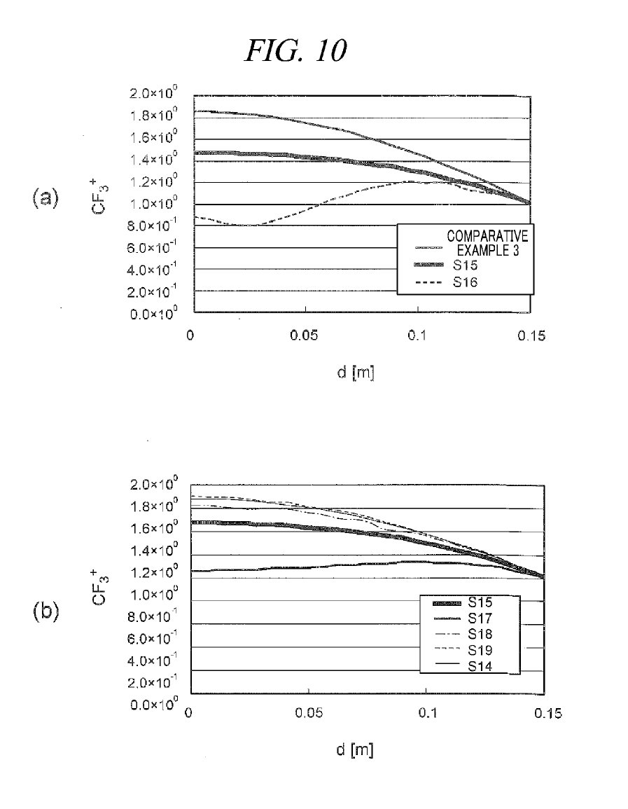

Hereinafter, simulation results of the plasma processing apparatus 10A shown in FIG. 6 will be described with reference to FIGS. 8 to 10. FIGS. 8 to 10 are graphs showing plasma distributions in a radial direction obtained through the simulations. The simulation results S15 to S19 of FIGS. 8 to 10 show an electron density distribution (FIG. 8), a fluorine (F) density distribution (FIG. 9), and a CF₃⁺ density distribution (FIG. 10), respectively. Here, the distributions are measured at a region upwardly spaced apart from the holding unit 22 by about 5 mm while variously changing the parameters of the plasma processing apparatus 10A through the simulations.

In FIGS. 8 to 10, horizontal axes indicate a distance d from the central axis line X in the radial direction. The vertical axis in FIG. 8 indicates electron density (Ne) normalized by electron density measured in a region with a radius of about 15 cm from the central axis line X. The vertical axis in FIG. 9 indicates fluorine density normalized by fluorine density measured in a region with a radius of about 15 cm from the central axis line X. The vertical axis in FIG. 10 indicates CF₃⁺ density normalized by CF₃⁺ density measured in a region with a radius of about 15 cm from the central axis line X.

The simulation results shown in FIGS. 8 to 10 are obtained when an argon (Ar) gas and a CHF₃ gas are used as processing gases and an internal pressure of the processing chamber 12 is set to be about 20 mTorr. Moreover, a flow rate ratio between the Ar gas and the CHF₃ gas is set to be about 500:25, and a gap between the top surface of the holding unit 22 and the bottom surface of the dielectric window 24 is set to be about 245 mm. The other parameters in the simulations of FIGS. 8 to 10 are given as follows.

S15: a diameter of a circular plate 80 being about 120 mm, and a distance between a bottom surface of a dielectric window 24 and a bottom surface of a circular plate 80 being about 150 mm
S16: a diameter of a circular plate 80 being about 120 mm, and a distance between a bottom surface of a dielectric window 24 and a bottom surface of a circular plate 80 being about 200 mm
S17: a diameter of a circular plate 80 being about 200 mm, and a distance between a bottom surface of a dielectric window 24 and a bottom surface of a circular plate 80 being about 150 mm
S18: a diameter of a circular plate 80 being about 200 mm, and a distance between a bottom surface of a dielectric window 24 and a bottom surface of a circular plate 80 being about 100 mm
S19: a diameter of a circular plate 80 being about 120 mm, and a distance between a bottom surface of a dielectric window 24 and a bottom surface of a circular plate 80 being about 100 mm

Referring to FIGS. 8 to 10, it can be seen that the simulation result (S14) using the dielectric rod 26 (a diameter of about 120 mm and a length of the dielectric rod within the processing space of about 100 mm) has substantially the same characteristics as the simulation result (S19) using the circular plate 80 (a diameter of about 120 mm and a distance between the bottom surface of the dielectric window 24 and its bottom surface of about 100 mm). That is, the circular plate 80 having the same diameter as that of the dielectric rod 26 within the processing space is provided such that the bottom surface of the circular plate 80 is located at the same position as the leading end of the dielectric rod 26. As a result, the circular plate 80 has the same plasma shielding effect obtained by the dielectric rod 26. Thus, the same plasma shielding effect obtained by the dielectric rod 26 can also be achieved by using the dielectric circular plate 80 made of a less dielectric material.

Referring to FIGS. 8 to 10, it is found that the electron density near the central axis line X can be reduced as compared to that in the comparative example 3 regardless of the types of the circular plates 80 of the simulation results (S15 to S19). It is also found that the electron density near the central axis line X can be effectively reduced by setting the circular plate 80 to have a diameter of about 120 mm or more. In addition, it can be seen that the electron density near the central axis line X can be more effectively reduced by setting the distance between the bottom surface of the circular plate 80 and the bottom surface of the dielectric window 24 to be about 150 mm or more, i.e., by setting the gap between the bottom surface of the circular plate 80 and the top surface of the holding unit 22 to be about 95 mm or less.

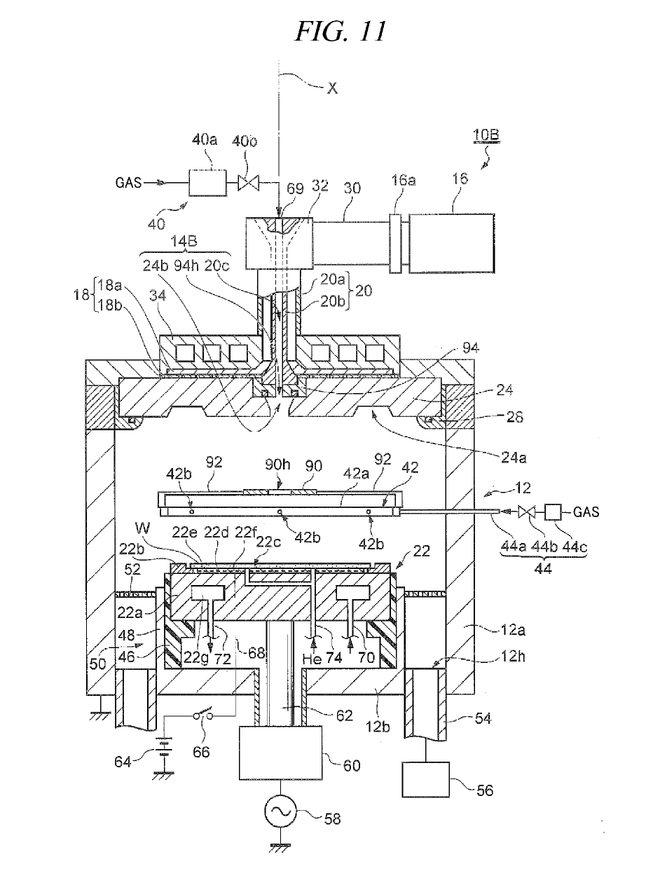

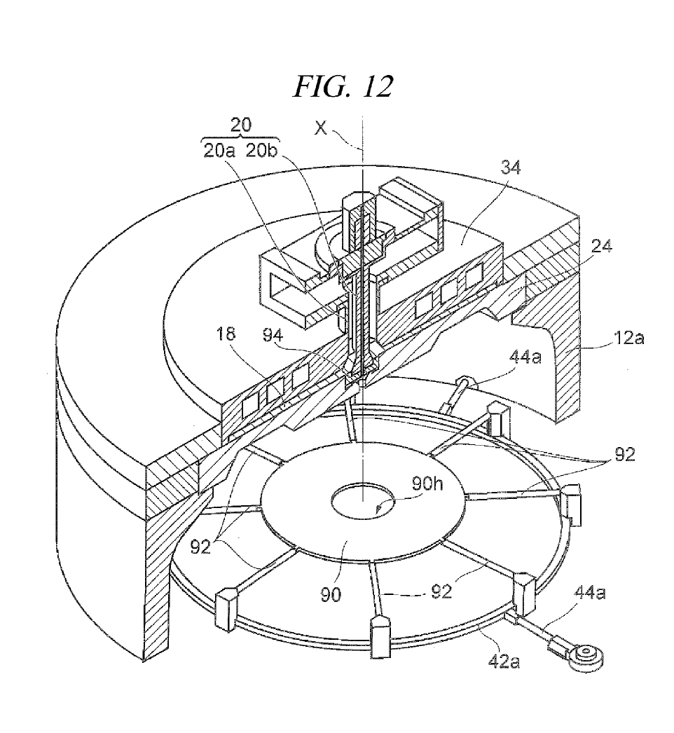

Hereinafter, a plasma processing apparatus in accordance with a third illustrative embodiment will be described. FIG. 11 is a cross sectional view schematically showing a plasma processing apparatus in accordance with the third illustrative embodiment. FIG. 12 is a broken perspective view showing some parts of the plasma processing apparatus shown in FIG. 11. Hereinafter, the differences between the plasma processing apparatus 10A and a plasma processing apparatus 10B shown in FIGS. 11 and 12 will be described.

The plasma processing apparatus 10B includes a circular plate 90 instead of the circular plate 80. The circular plate 90 is made of a dielectric material and has a substantially circular plate shape. The circular plate 90 is made of, e.g., quartz, alumina or the like. The circular plate 90 is provided on a surface perpendicular to the central axis line X within the processing space between the dielectric window 24 and the holding unit 22. That is, the circular plate 90 is positioned at the central region, as in the case of the circular plate 80. Therefore, the plasma in the central region is shielded by the circular plate 90. As a result, at a portion perpendicular to the central axis line X, a processing rate for the processing target substrate W is decreased.

A radius of the circular plate 90 is greater than or equal to about 60 mm. By setting the dielectric circular plate 90 to have a radius of about 60 mm or more, plasma density in a region directly above the holding unit 22 near the central axis line X can be effectively reduced. Further, a distance (gap) between the bottom surface of the circular plate 90 and the top surface of the holding unit 22 is smaller than or equal to about 95 mm. Due to the gap, the plasma density in the region directly above the holding unit near the central axis line X can be more effectively reduced.

In the present illustrative embodiment, the circular plate 90 is supported at the gas pipe 42a by a multiple number of supporting rods 92 made of a dielectric material. The multiple number of supporting rods 92 extend in a radial direction with respect to the central axis line X. The supporting rods 92 are connected to an edge portion of the circular plate 90 and the gas pipe 42a. The supporting rods 92 are spaced apart from each other at a regular interval in a circumferential direction of the circular plate 90. That is, the circular plate 90 can be supported by the supporting rods 92 without using the dielectric rod extending along the central axis line X. The supporting rods 92 are made of, e.g., quartz, alumina or the like.

The number of the supporting rods 92 is not particularly limited as long as the circular plate 90 is supported. For example, two or more supporting rods may be used. In the present illustrative embodiment, four or more supporting rods 92 may be provided. By supporting the circular plate 90 with four or more supporting rods 92, the plasma density distribution in a region directly above the holding unit 22 can be more uniform along the circumferential direction. In the present illustrative embodiment, eight or more supporting rods 92 may be provided. By supporting the circular plate 90 with eight or more supporting rods 92, the plasma density distribution in the region directly above the holding unit 22 can be more uniform along the circumferential direction. Further, in the present illustrative embodiment, a thickness of the supporting rod 92 is smaller than or equal to about 5 mm. By using the supporting rods 92 having a thickness of about 5 mm or less, the plasma density distribution in the region directly above the holding unit 22 can be more uniform along the circumferential direction.

The plasma processing apparatus 10B further includes an injector base 94. The injector base 94 is provided within the hole 24b and is positioned upwardly of the bottom surface of the dielectric window 24 toward the dielectric plate 18a. A sealing member such as an O-ring is provided between the injector base 94 and the dielectric window 24. The injector base 94 is made of alumite-treated aluminum, Y₂O₃ (yttria)-coated aluminum or the like. The injector base 94 is electrically grounded.

A hole 94h communicating with the inner hole 20c of the inner conductor 20b is formed in the injector base 94. A gas supply unit 14B of the plasma processing apparatus 10B includes the inner hole 20c of the inner conductor 20b, the hole 94h of the injector base 94, and the hole 24b of the dielectric window 24. That is, the gas supply unit 14B of the plasma processing apparatus 10B is partitioned by the inner conductor 20b, the injector base 94 and the dielectric window 24.

In the present illustrative embodiment, a hole 90h extending along the central axis line X is formed in the circular plate 90. That is, the circular plate 90 is an annular plate. A processing gas introduced from the gas supply unit 14B may flow along the central axis line X through the hole 90h. The hole 90h may have a diameter of about 60 mm or less. By setting the hole 90h of the circular plate 90 to have a diameter of about 60 mm or less, it is possible to prevent the plasma shielding effect in the central region to be deteriorated.

In the present illustrative embodiment, a distance between the gas pipe 42a and the holding unit 22 in the central axis line X is set to be shorter than the distance between the circular plate 90 and the holding unit 22 along the central axis line X. That is, the gas pipe 42a is provided below the circular plate 90 along the central axis line X. Further, the processing gas is discharged from the gas pipe 42a, which is positioned radially farther out than a peripheral portion of the circular plate 90, toward the central axis line X in a radial direction, i.e., in a direction perpendicular to the central axis line X.

After discharging from the gas discharge holes 42b of the gas pipe 42a toward the central axis line X, the discharged processing gas is split into an updraft gas flow and a downdraft gas flow. The updraft gas flow can be changed to a downdraft gas flow by the circular plate 90. Due to the flow of the processing gas, a processing rate in a region (i.e., middle region) between a central portion and an edge portion of the processing target substrate W, or a processing rate at the edge of the processing target substrate W becomes similar to a processing rate at the central portion of the processing target substrate W. As a result, etching profile non-uniformity of the processing target substrate W in the radial direction can be reduced.

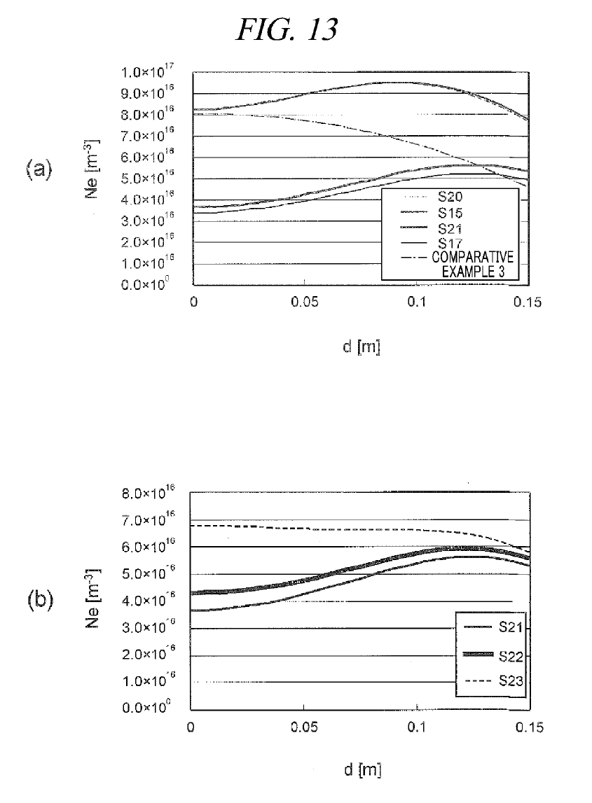

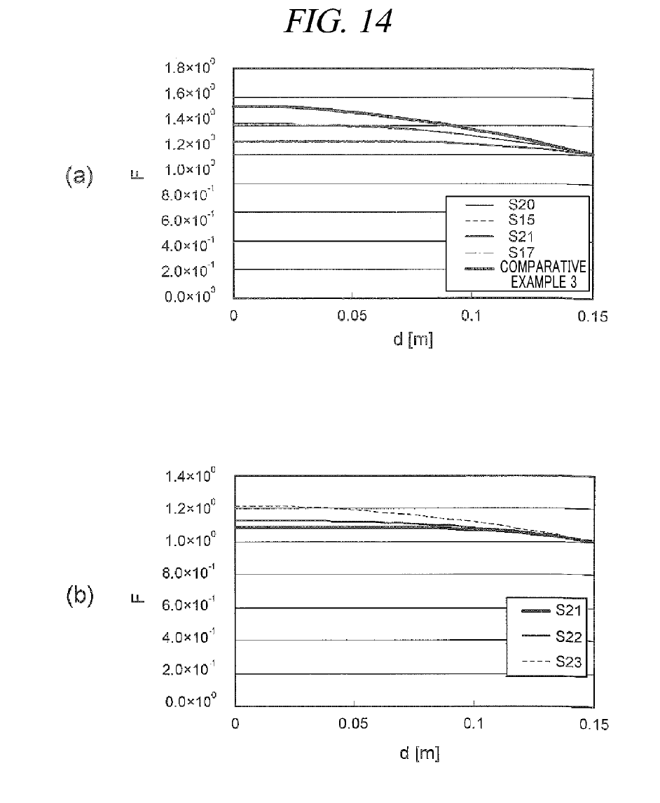

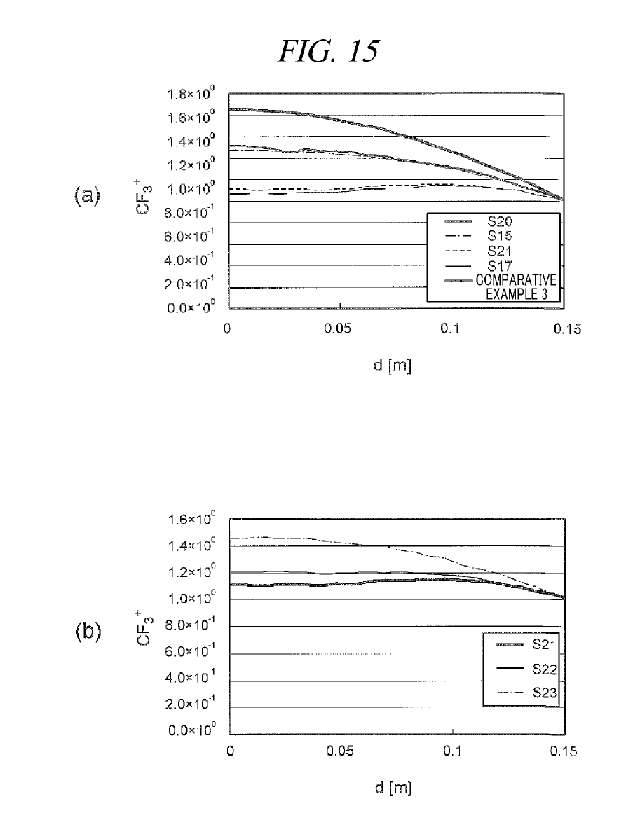

Hereinafter, simulation results of the plasma processing apparatus 10B shown in FIG. 11 will be described with reference to FIGS. 13 to 15. FIGS. 13 to 15 are graphs showing plasma distributions in a radial direction obtained through the simulations. The simulation results S21 and S23 of FIGS. 13 to 15 show an electron density (Ne) distribution in the radial direction (FIG. 13), a fluorine (F) density distribution in the radial direction (FIG. 14), and a CF₃⁺ density distribution in the radial direction (FIG. 15), respectively. Here, the distributions are measured at a region upwardly spaced apart from the holding unit 22 by about 5 mm while variously changing the parameters of the plasma processing apparatus 10B through the simulations.

In FIGS. 13 to 15, horizontal axes indicate a distance d from the central axis line X in the radial direction. A vertical axis in FIG. 13 indicates electron density (Ne) [m⁻³]. A vertical axis in FIG. 14 indicates a fluorine density normalized by fluorine density measured in a region with a radius of about 15 cm from the central axis line X. A vertical axis in FIG. 15 indicates CF₃⁺ density normalized by CF₃⁺ density measured in a region with a radius of about 15 cm from the central axis line X.

The simulation results shown in FIGS. 13 to 15 are obtained when an Ar gas and a CHF₃ gas are used as processing gases and an internal pressure of the processing chamber 12 is set to be about 20 mTorr. Moreover, a flow rate ratio between the Ar gas and the CHF₃ gas is set to be about 500:25, and a gap between the top surface of the holding unit 22 and the bottom surface of the dielectric window 24 is set to be about 245 mm. The other parameters of the simulations of FIGS. 13 to 15 are given as follows.

S20: a diameter of a circular plate 90 being about 120 mm, no hole 90h, a distance between a bottom surface of a dielectric window 24 and a bottom surface of a circular plate 90 being about 150 mm, and no supporting rod 92.

S21: a diameter of a circular plate 90 being about 200 mm, no hole 90h, a distance between a bottom surface of a dielectric window 24 and a bottom surface of a circular plate 90 being about 150 mm, and no supporting rod 92
S22: a diameter of a circular plate 90 being about 200 mm, a diameter of a hole 90h being about 60 mm, a distance between a bottom surface of a dielectric window 24 and a bottom surface of a circular plate 90 being about 150 mm, and no supporting rod 92
S23: a diameter of a circular plate 90 being about 200 mm, a diameter of a hole 90h being about 100 mm, a distance between a bottom surface of a dielectric window 24 and a bottom surface of a circular plate 90 being about 150 mm, and no supporting rod 92

As can be clearly seen from the comparison between the simulation results (S20 and S15) and between the simulation results (S21 and S17) shown in FIGS. 13(a), 14(a) and 15(a), the same plasma shielding effect can be provided by the circular plate 80 supported by the dielectric rod 82 and the circular plate 90 without using the dielectric rod 82. Since the circular plate 90 without using the dielectric rod 82 is easily manufactured, the plasma processing apparatus 10B can achieve a desired plasma shielding effect at a lower cost.

Referring to FIGS. 13 to 15, it is found that the electron density near the central axis line X can be reduced as compared to that in the comparative example 3 regardless of the types of the circular plates 90 of the simulation results (S21 to S23). It is also found that the electron density near the central axis line X can be effectively reduced by setting the circular plate 90 to have the diameter of about 120 mm or more. In addition, it is found that the electron density near the central axis line X can be more effectively reduced by setting the distance between the bottom surface of the circular plate 90 and the bottom surface of the dielectric window 24 to be about 150 mm or more, i.e., by setting the gap between the bottom surface of the circular plate 90 and the top surface of the holding unit 22 to be about 95 mm or less. Referring to FIGS. 13(b), 14(b) and 15(b), it can be seen that it is possible to prevent the plasma shielding effect in the central region by the circular plate 90 from being deteriorated by setting the hole 90h to have the diameter of about 60 mm or less.

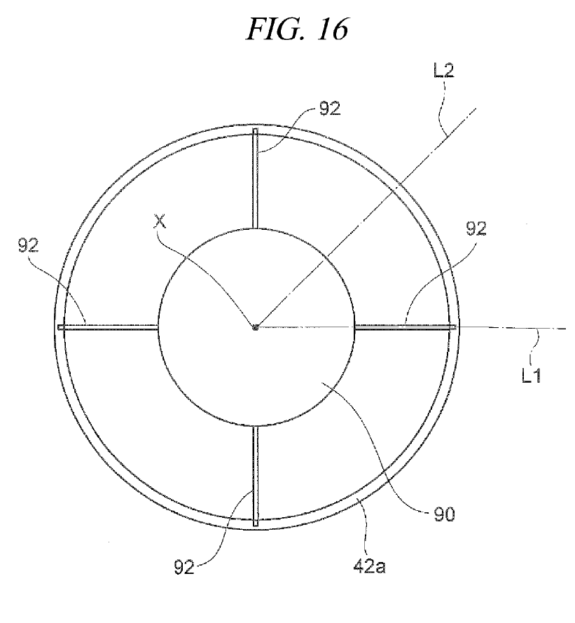

Hereinafter, simulation results performed to examine the effect of the supporting rods 92 will be described. The simulation results are obtained when an Ar gas and a CHF₃ gas are used as processing gases and an internal pressure of the processing chamber 12 is set to be about 20 mTorr. Further, a flow rate ratio between the Ar gas and the CHF₃ gas is set to be about 500:25, and a gap between the top surface of the holding unit 22 and the bottom surface of the dielectric window 24 is set to be about 245 mm. In addition, a diameter of the circular plate 90 is set to be about 120 mm; a hole 90h is not formed; and a distance between the bottom surface of the dielectric window 24 and the bottom surface of the circular plate 90 is set to be about 150 mm. The simulation result S24 is obtained by measuring electron density distributions on lines L1 and L2 shown in FIG. 16 by using four supporting rods 92, each having a thickness of about 5 mm, spaced apart from each other at a regular interval along a circumferential direction. The simulation result S25 is obtained by measuring electron density distributions on the lines L1 and L2 by using four supporting rods 92, each having a thickness of about 10 mm, spaced apart from each other at a regular interval along a circumferential direction. Here, the line L1 is a straight line, extending in a radial direction directly below the supporting rods 92, upwardly spaced apart from the holding unit 22 by about 5 mm. The line L2 is a straight line, extending in a radial direction directly below a position between adjacent supporting rods 92, upwardly spaced apart from the holding unit 22 by about 5 mm.

Based on the simulation results S24 and S25, uniformity of the electron density in the circumferential direction is evaluated by the following Eq. (1). As an absolute value of an evaluation value U obtained by the following Eq. (1) is decreased, the uniformity of the electron density in the circumferential direction is increased.

U=(P−Q)/(P+Q)×100 Eq. (1)

P: maximum electron density within a range of about 15 cm from the central axis line X among electron densities measured on the line L2
Q: minimum electron density within the range of about 15 cm from the central axis line X among electron densities measured on the line L1

The evaluation value U of the simulation result S24 obtained by the Eq. (1) is about 3.37, and the evaluation value U of the simulation result S25 obtained by the Eq. (1) is about 7.61. From these simulation results, it can be seen that when the thickness of the supporting rod 92 is set to be smaller than or equal to about 5 mm, it is possible to uniformize the plasma distribution in the circumferential direction.

The simulation results (S26, S27, and S28) are obtained by measuring electron density distributions on the lines L1 and L2 under the same conditions as those in the simulation result S24 while varying the number of the supporting rods 92 to four, eight and sixteen. The evaluation value U of the simulation result S26 obtained by the Eq. (1) is about 3.39; the evaluation value U of the simulation result S27 obtained by the Eq. (1) is about 1.05; and the evaluation value U of the simulation result S28 obtained by the Eq. (1) is about −0.08. From these simulation results, it can be seen that when the number of the supporting rods 92 is four or more, the plasma distribution in the circumferential direction can be more uniform. It can be also seen that when the number of the supporting rods 92 is eight or more, the plasma distribution in the circumferential direction can be more uniform.

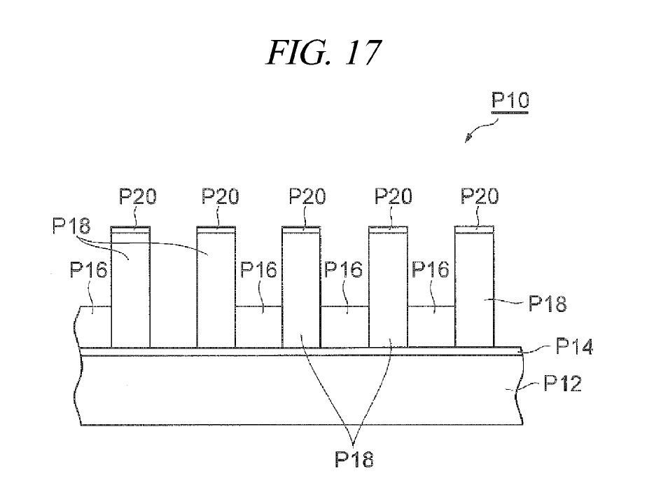

Hereinafter, evaluation experiments E1 and E2 performed by using the plasma processing apparatus 10B shown in FIG. 11 will be described with reference to FIG. 17. FIG. 17 schematically shows a sample for an evaluation experiment. A sample P10 shown in FIG. 17 is obtained by forming a multiple number gates of fin-shaped FET (Field Effect Transistor) by an etching process. In the sample P10, a SiO₂ layer P14 serving as an etching stopper layer is formed on a surface of a Si substrate P12. Moreover, substantially rectangular parallelepiped fins P16 are formed on the layer P14. Through subsequent processes, the fins P16 becomes source regions, drain regions and channel regions. In the sample P10, a multiple number of Si gates P18 are formed so as to cover the channel regions of the fins P16. Further, a SiN layer P20 is formed on top surfaces of the gates P18, respectively, and the layer P20 is used as an etching mask when the gates P18 are formed by the etching process.

In order to form the gates P18 of the sample P10, a Si semiconductor layer is formed on the layer P14 and the fins P16, the layer P20 having a certain pattern is formed on the Si semiconductor layer, and, then, the Si semiconductor layer is etched by using the layer P20 as a mask.

In the evaluation experiments E1 and E2, the gates P18 of the sample P10 are formed by using the plasma processing apparatus 10B shown in FIG. 11. In the evaluation experiments E1 and E2, a height of the gate P18, a width of the gate P18 and a gap between adjacent gates P18 are set to be about 200 nm, about 30 nm and about 30 nm, respectively. Further, a diameter of the processing target substrate W is set to be about 300 mm. In the evaluation experiments E1 and E2, an internal pressure of the processing chamber 12 is set to be about 100 mTorr; microwave having a frequency of about 2.45 GHz is supplied from the microwave generator 16 at a power level of about 2500 W; a RF bias of about 150 W is applied from the high frequency power supply 58; a processing gas containing an Ar gas having a flow rate of about 1000 sccm, a HBr gas having a flow rate of about 800 sccm and an O₂ gas having a flow rate of about 10 sccm is supplied from the gas supply units 14B and 42. The other conditions in the evaluation experiments E1 and E2 are set as follows.

<E1>

Flow rate ratio (flow rate of the gas supply unit 14B:flow rate of the gas supply unit 42): 60:40
Diameter of the circular plate 90: 150 mm
Diameter of the hole 90h: 60 mm
Distance from the bottom surface of the dielectric window 24 to the bottom surface of the circular plate 90: 150 mm
Gap between the top surface of the holding unit 22 and the bottom surface of the dielectric window 24: 245 mm
Number of the supporting rods 92: 8
Thickness of the supporting rod 92: 5 mm
Etching time: 80 sec

<E2>

Flow rate ratio (flow rate of the gas supply unit 14B:flow rate of the gas supply unit 42): 65:35
Diameter of the circular plate 90: 200 mm
Diameter of the hole 90h: 60 mm
Distance from the bottom surface of the dielectric window 24 to the bottom surface of the circular plate 90: 150 mm
Gap between the top surface of the holding unit 22 and the bottom surface of the dielectric window 24: 245 mm
Number of the supporting rods 92: 8
Thickness of the supporting rod 92: 5 mm
Etching time: 100 sec

In a comparative experiment SE1, a sample P10 is formed by using a plasma processing apparatus that is different from the plasma processing apparatus 10B in that the circular plate 90 is not provided. Hereinafter, the different conditions between the comparative experiment SE1 and the evaluation experiments E1 and E2 will be described.

Flow rate of O₂: 14 sccm
Flow rate ratio (flow rate of the gas supply unit 14:flow rate of the gas supply unit (42): 70:30
Etching time: 65 sec

SEM images of the samples P10 formed by the evaluation experiments E1 and E2 and the comparative experiment SE1 are obtained. From the SEM images, widths of the gates P18 near the layer P14 formed at the central portion of the processing target substrate W (hereinafter, referred to as a “central gate width”) are measured, and widths of the gates P18 near the layer P14 which are formed at the edge portion of the processing target substrate W (hereinafter, referred to as an “edge gate width”) are measured. As a result, in the sample P10 obtained by the evaluation experiment E1, the difference between the central gate width and the edge gate width is about 0.5 nm. In the sample P10 obtained by the evaluation experiment E2, the difference between the central gate width and the edge gate width is about 1.8 nm. Meanwhile, in the sample P10 obtained by the comparative experiment SE1, the difference between the central gate width and the edge gate width is about 4.5 nm. From the above results, it can be seen that the plasma processing apparatus 10B can reduce the etching profile non-uniformity of the processing target substrate W in the radial direction.

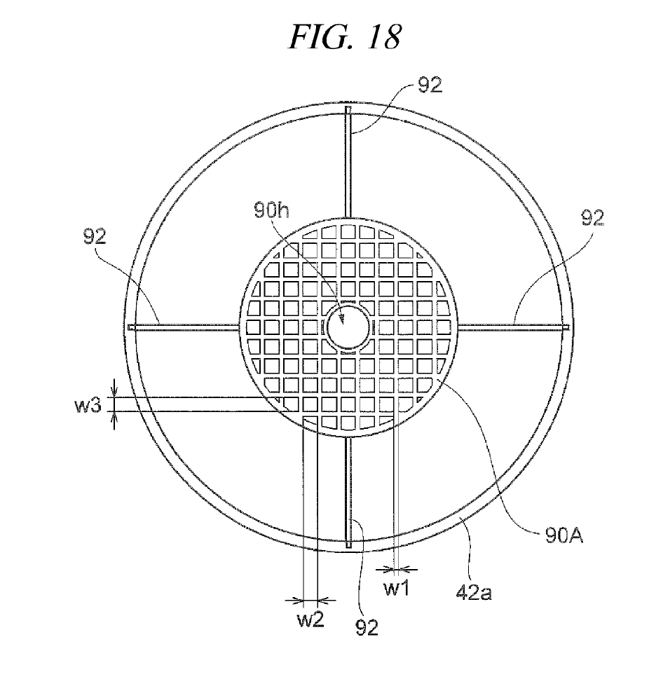

Hereinafter, a fourth illustrative embodiment will be described. FIG. 18 shows a circular plate in accordance with the fourth illustrative embodiment. In the plasma processing apparatus 10B, a circular plate 90A shown in FIG. 18 is used instead of the circular plate 90. The circular plate 90A is a mesh-shaped circular plate made of a dielectric material. That is, a multiple number of mesh holes are formed in the circular plate 90A. In the present illustrative embodiment, as shown in FIG. 18, a hole 90h is formed in the central portion of the circular plate 90A, as in the case of the circular plate 90. That is, the circular plate 90A is formed of a mesh-shaped annular plate. In the present illustrative embodiment, the mesh holes formed in the circular plate 90A have a rectangular shape when viewed from the top. That is, the circular plate 90A includes a dielectric lattice formed by walls extending in two directions perpendicular to each other, and the mesh holes are partitioned by the walls of the lattice. By using this circular plate 90A, the electron density near the central axis line X can be reduced. Further, by appropriately adjusting the size of the mesh holes, the amount of discharged gas, which is split into an updraft gas flow and a downdraft gas flow, from the gas discharge holes 42b of the gas pipe 42a can be controlled.

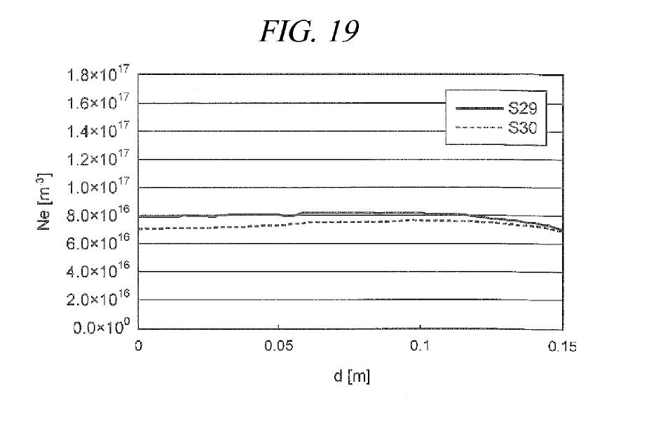

Hereinafter, simulation results S29 and S30 of the plasma processing apparatus 10B having the circular plate 90A shown in FIG. 19 will be described. FIG. 19 shows an electron density distribution in a radial direction measured at a region upwardly spaced apart from the holding unit 22 by about 5 mm while variously changing the parameters of the plasma processing apparatus 10B having the circular plate 90A through the simulation. In FIG. 19, a horizontal axis indicates a distance d from the central axis line X in the radial direction, and a vertical axis indicates electron density (Ne) [m⁻³]. The simulation results (S29 and S30) shown in FIG. 19 are obtained when an Ar gas is used as a processing gas and an internal pressure of the processing chamber 12 is set to be about 20 mTorr. Further, a gap between the top surface of the holding unit 22 and the bottom surface of the dielectric window 24 is set to be about 245 mm. The other parameters of the simulation of FIG. 19 are given as follows.

<S29>

Diameter of the circular plate 90A: 200 mm
Hole 90h: omitted
Distance from the bottom surface of the dielectric window 24 to the bottom surface of the circular plate 90A: 150 mm
Supporting rod 92: omitted
Width of a wall of the lattice w1: 5 mm
Size of a rectangular mesh hole (w2×w3): 14.5 mm×14.5 mm

<S30>

Diameter of the circular plate 90A: 200 mm
Hole 90h: omitted
Distance from the bottom surface of the dielectric window 24 to the bottom surface of the circular plate 90A: 150 mm
Supporting rod 92: omitted
Width of a wall of the lattice w1: 5 mm
Size of a rectangular mesh hole (w2×w3): 27.5 mm×27.5 mm

As can be clearly seen from FIG. 19, even when the mesh-shaped circular plate 90A is used, the electron density near the central axis line X can be reduced. That is, it is found that a relatively uniform plasma density distribution in the diametrical direction is obtained.

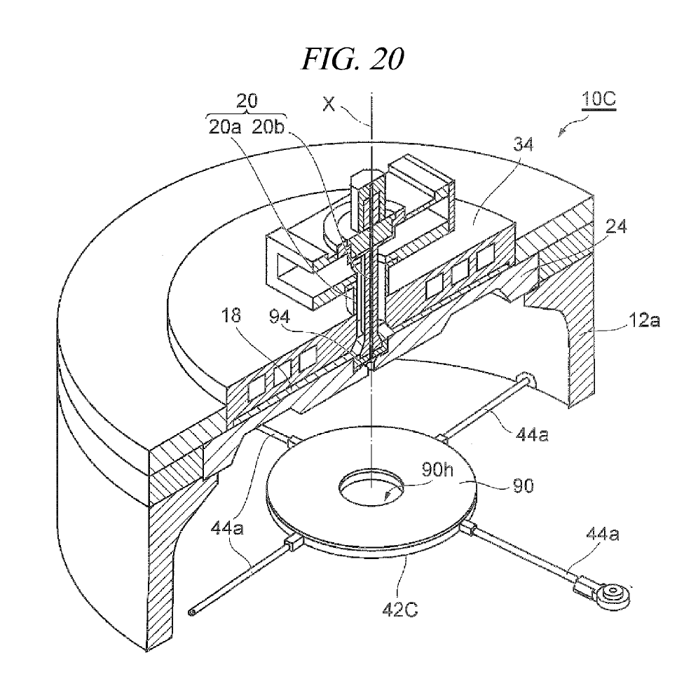

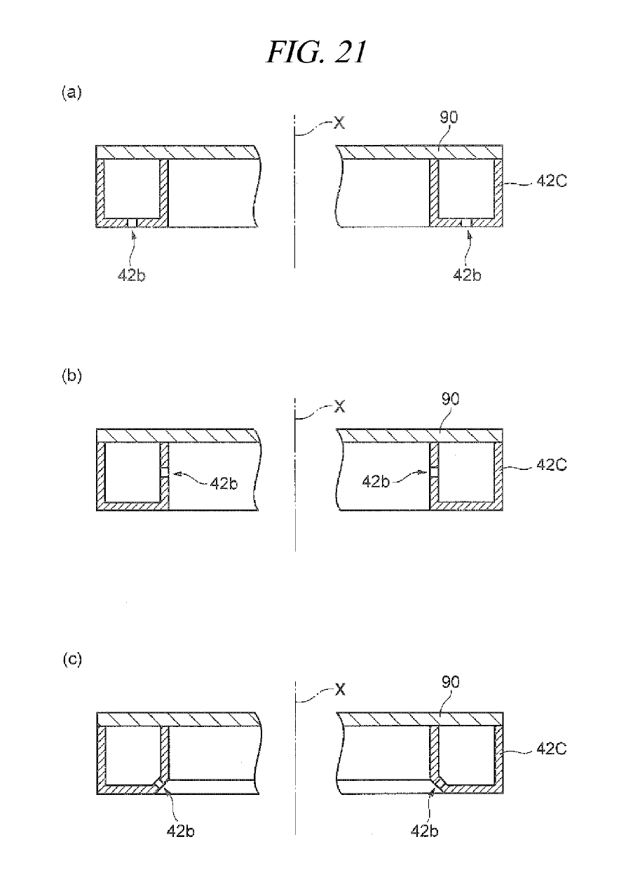

Hereinafter, a plasma processing apparatus in accordance with the fourth illustrative embodiment will be described. FIG. 20 is a broken perspective view showing some parts of a plasma processing apparatus in accordance with the fourth illustrative embodiment. A plasma processing apparatus 10C shown in FIG. 20 is different from the plasma processing apparatus 10B in that a gas pipe 42C is provided instead of the gas pipe 42a. The gas pipe 42C is positioned directly below the circular plate 90 along the central axis line X. Like the gas pipe 42a, the gas pipe 42C also has an annular shape centered about the central axis line X. The gas pipe 42C has a multiple number of gas discharge holes 42b (see FIG. 21). The gas pipe 42C is made of a dielectric material such as quartz.

FIG. 21 provides cross sectional views schematically showing structures of the gas pipe provided in the plasma processing apparatus shown in FIG. 20. FIGS. 21(a) to 21(c) illustrate various structures of the gas pipe 42C in a cross section parallel to the central axis line X. As shown in FIGS. 21(a) to 21(c), in the present illustrative embodiment, the gas pipe 42C is in contact with the bottom surface of the circular plate 90 along the outer peripheral portion of the circular plate 90. When the gas pipe 42C is not in contact with the circular plate 90, a cross section of the gas pipe 42C is upwardly open. That is, an annular processing gas passage is partitioned by the gas pipe 42C and the circular plate 90. In the fourth illustrative embodiment, the gas pipe 42C is in contact with the bottom surface of the circular plate 90 in a region between the outer peripheral portion and the central portion of the circular plate 90.

As shown in FIG. 21(a), a multiple number of gas discharge holes 42b of the gas pipe 42C are oriented to discharge gas in a downward direction. That is, the processing gas is downwardly discharged from the gas discharge holes 42b. As shown in FIG. 21(b), the gas discharge holes 42b of the gas pipe 42C are oriented to discharge gas toward the central axis line X. That is, the processing gas is discharged toward the central axis line X from the gas discharge holes 42b. As shown in FIG. 21(c), the gas discharge holes 42b of the gas pipe 42C are oriented to discharge gas in an obliquely downward direction. That is, the processing gas is discharged obliquely downward from the gas discharge holes 42b.

In accordance with the plasma processing apparatus 10C, in addition to the effect obtained by the circular plate 90, by appropriately adjusting a direction of a gas discharged from the gas pipe 42C, it is possible to achieve an effect of controlling the amount of gas supplied toward a certain portion of the processing target substrate W. For example, it is possible to increase the amount of gas supplied toward a middle portion of the processing target substrate W (i.e., a region between the central portion and the edge portion of the processing target substrate W) in the radial direction or the amount of gas supplied to the edge of the processing target substrate W in the radial direction. As a result, the non-uniformity of the processing rate in the radial direction of the processing target substrate W can be reduced, and the etching profile non-uniformity of the processing target substrate W in the radial direction can be reduced.

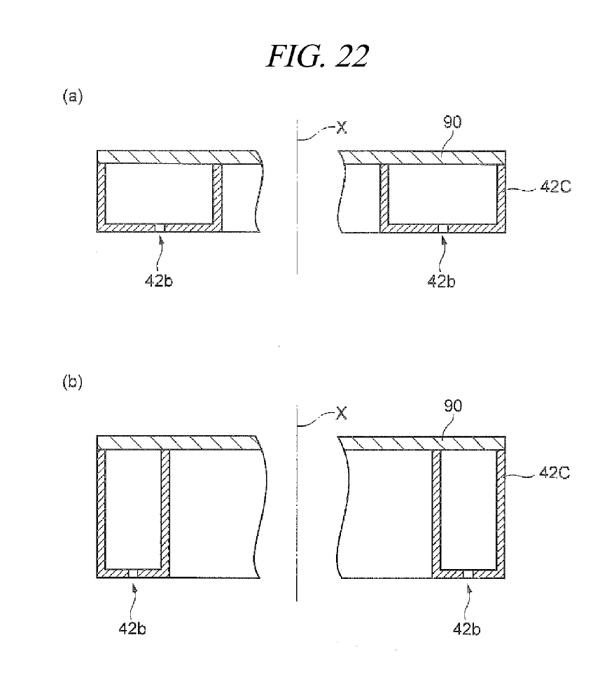

Hereinafter, there will be explained with reference with FIG. 22. FIG. 22 provides cross sectional views schematically showing structures of the gas pipe provided in the plasma processing apparatus shown in FIG. 20. In the plasma processing apparatus 10C, a gas pipe shown in FIG. 22 is provided instead of the gas pipe shown in FIG. 21. The gas pipe 42C of FIG. 21 has a cross section of a square shape. However, a gas pipe 42C of FIG. 21 has a cross section of a substantially rectangular shape. Specifically, a cross section of the gas pipe 42C has a width in a direction perpendicular to the central axis line X, i.e., in a radial direction greater than a width in a direction parallel to the central axis line X. A pressure of the gas supplied into the gas pipe 42C from the gas pipe 44a would be decreased when the gas flows in the gas pipe 42C. However, by setting the width of the gas pipe 42C in the radial direction to be large, a pressure loss in the gas pipe 42C can be decreased while reducing manufacturing cost of the gas pipe 42C. As a result, the gas discharged from the gas discharge holes 42b can be uniformly supplied by the gas pipe 42C shown in FIG. 22.

Further, as depicted in FIG. 22(b), the gas pipe 42C may have the width of the gas pipe 42C in the direction parallel to the central axis line X larger than the width of the gas pipe 42C in the direction perpendicular to the central axis line X. Further, as illustrated in FIGS. 21(b) and 21(c), the gas discharge holes 42b of the gas pipe 42C shown in FIG. 22 may be oriented to discharge gas toward the central axis line X, or may be oriented to discharge gas obliquely downward.

While various illustrative embodiments have been described, the present disclosure is not limited thereto, but may be variously modified. For example, in the above simulations, an etching gas is used as a processing gas. However, the plasma processing apparatus of the present disclosure can also be applied to a plasma CVD (chemical vapor deposition) apparatus.

What is claimed is:

1. A plasma processing apparatus comprising:
a processing chamber;
a gas supply unit for supplying a processing gas into the processing chamber;
a microwave generator for generating microwave;
an antenna for introducing the microwave for plasma excitation into the processing chamber;
a coaxial waveguide provided between the microwave generator and the antenna;
a holding unit, disposed to face the antenna in a direction of a central axis line of the coaxial waveguide, for holding a processing target substrate;
a dielectric window, provided between the antenna and the holding unit, for transmitting the microwave from the antenna into the processing chamber; and
a dielectric rod provided in a region between the holding unit and the dielectric window along the central axis line.

2. The plasma processing apparatus of claim 1,
wherein a distance between a leading end of the dielectric rod which faces the holding unit and the holding unit is smaller than or equal to about 95 mm.

3. The plasma processing apparatus of claim 1,
wherein a radius of the dielectric rod is greater than or equal to about 60 mm.

4. The plasma processing apparatus of claim 1,
wherein the gas supply unit is configured to supply the processing gas from the antenna side to the holding unit side along the central axis line; and
the dielectric rod is provided with one or more holes through which the processing gas supplied from the gas supply unit passes, and the holes extend along the central axis line.

5. The plasma processing apparatus of claim 4,
wherein a metal film is formed on inner surfaces of the holes.

6. A plasma processing apparatus comprising:
a processing chamber;
a gas supply unit for supplying a processing gas into the processing chamber;
a microwave generator for generating microwave;
an antenna for introducing the microwave for plasma excitation into the processing chamber;
a coaxial waveguide provided between the microwave generator and the antenna;
a holding unit, disposed to face the antenna in a direction of a central axis line of the coaxial waveguide, for holding a processing target substrate;
a dielectric window, provided between the antenna and the holding unit, for transmitting the microwave from the antenna into the processing chamber; and
a circular plate provided in a region between the holding unit and the dielectric window along a plane perpendicular to the central axis line.

7. The plasma processing apparatus of claim 6,
wherein a distance between the circular plate and the holding unit is smaller than or equal to about 95 mm.

8. The plasma processing apparatus of claim 6,
wherein a radius of the circular plate is greater than or equal to about 60 mm.

9. The plasma processing apparatus of claim 6,
wherein the circular plate is supported by a dielectric rod that has a diameter smaller than a diameter of the circular plate and is provided along the central axis line.

10. The plasma processing apparatus of claim 9,
wherein the gas supply unit is configured to supply the processing gas from the antenna side to the holding unit side along the central axis line, and
the dielectric rod is provided with one or more holes through which the processing gas supplied from the gas supply unit passes, and the holes extend along the central axis line.

11. The plasma processing apparatus of claim 6,
wherein the gas supply unit is configured to supply the processing gas from the antenna side to the holding unit side along the central axis line, and
the circular plate is provided with a hole extending along the central axis line.

12. The plasma processing apparatus of claim 11,
wherein a diameter of the hole formed in the circular plate is smaller than or equal to about 60 mm.

13. The plasma processing apparatus of claim 6, further comprising:
a gas pipe, formed in an annular shape centered about the central axis line, having a plurality of gas discharge holes,
wherein the circular plate is supported by the gas pipe.

14. The plasma processing apparatus of claim 13, further comprising:
a plurality of supporting rods extending in a radial direction with respect to the central axis line and coupled to the gas pipe and the circular plate, the supporting rods being made of dielectric material.

15. The plasma processing apparatus of claim 14,
wherein a thickness of each of the supporting rods is smaller than or equal to about 5 mm.

16. The plasma processing apparatus of claim 13,
wherein the gas pipe is provided directly below the circular plate in a direction of the central axis line.

17. The plasma processing apparatus of claim 16,
wherein the gas pipe is provided along an outer periphery of the circular plate and is in contact with a bottom surface of the circular plate.

18. The plasma processing apparatus of claim 16,
wherein the gas discharge holes of the gas pipe are configured to discharge a gas downward.

19. The plasma processing apparatus of claim 13,
wherein a cross section of the gas pipe has a first width in a direction perpendicular to the central axis line and a second width in a direction parallel to the central axis line, and, the first width is larger than the second width or the second width is larger than the first width.

20. The plasma processing apparatus of claim 13, wherein the gas supply unit includes an injector base disposed in the dielectric window.
